(19) United States
(12) Patent Application Publication
(10) Pub. No.: US 2014/0204539 A1
(43) Pub. Date: Jul. 24, 2014

(54) PACKAGE AND TRAY SYSTEM FOR INTERCHANGING DEVICE COMPONENTS

(71) Applicant: BRADLEY DEAN LOOMIS, PULLMAN, WA (US)

(72) Inventor: BRADLEY DEAN LOOMIS, PULLMAN, WA (US)

(21) Appl. No.: 14/155,141

(22) Filed: Jan. 14, 2014

Related U.S. Application Data
(60) Provisional application No. 61/756,239, filed on Jan. 24, 2013.

(51) Int. Cl. H05K 7/10

(52) U.S. Cl. CPC H05K 7/10
USPC 361/731

(57) ABSTRACT

Some embodiments of the invention include a package and tray system for modularizing a set of component hardware devices of an electronic device. The system includes at least one package and a tray. Each package fits into the tray by an alignment notch that aligns the package for interlocking within the tray. In some embodiments, the system includes several packages that simultaneously fit into the tray. In some embodiments, the packages include a CPU package, a Wi-Fi package, a battery package, a SIM card package, and a camera package. In some embodiments, a minimum package configuration includes the CPU package, the memory package, and the battery package.

### CLAIM OF BENEFIT TO PRIOR APPLICATION

This application claims benefit to U.S. Provisional Patent Application 61/756,239, entitled “Package And Tray System For Interchanging Device Components,” filed Jan. 24, 2013. The U.S. Provisional Patent Application 61/756,239 is incorporated herein by reference.

### BACKGROUND

Most electronic devices use several different technologies embodied in several different hardware components. For example, a smart phone may include a wireless receiver, a battery, a SIM card, a camera, and many other hardware devices. A person who owns any single electronic device is likely to own several electronic devices. For example, the person may own a smart phone, a digital camera, a tablet computing device, a media player, etc. Each electronic device utilizes its own combination of such component hardware devices. However, many component hardware devices are common across multiple different electronic devices. For instance, a smart phone and a digital camera may both use functionally equivalent charge coupled devices (CCDs) or CMOS sensors. However, most component hardware devices of an electronic device are not interchangeable with other electronic devices, despite the common utilization of one or more technologies. This is a problem for many users who upgrade devices or make buying decisions based on a package of component hardware devices onboard a particular device. For example, a person may have to purchase a new smart phone because the wireless receiver on the person's old smart phone stopped working, but the person would like to retain a set of the old smart phone's component hardware devices (e.g., camera, audio, etc.) on the new smart phone. Unfortunately, very few interchangeable component hardware devices exist for any electronic device. In many cases, such interchangeable component hardware devices are limited to SIM cards and batteries. Most or all of the other component hardware devices are not modularized in any way that allows them to be used across devices. This is problematic because it leads to unnecessary electronic and material waste. It also discourages consumer loyalty by preventing simple upgrades of devices for consumers wishing to minimize costs (e.g., upgrading a first package of interworking component hardware devices while retaining an existing second package of other interworking component hardware devices).

### BRIEF SUMMARY

Some embodiments of the invention include novel package and tray system for modularizing a set of component hardware devices of an electronic device. In some embodiments, the system includes at least one package and a tray. Each package fits into the tray by an alignment notch that aligns the package for interlocking within the tray. In some embodiments, the system includes a plurality of packages that simultaneously fit into the tray. In some embodiments, the plurality of packages comprises a CPU package, a Wi-Fi package, a battery package, a SIM card package, and a camera package. In some embodiments, a minimum package configuration comprises the CPU package, the memory package, and the battery package.

In some embodiments, the electronic device is a mobile device. In some embodiments, the mobile device is a smart phone. In these embodiments, the package and tray system modularizes a Wi-Fi package, a battery package, a SIM card package, and a camera package. The system in these embodiments fits the modularized set of packages into a tray of the smart phone to make the smart phone operationally functional.

In other embodiments, the mobile device is a table computing device. In these embodiments, the package and tray system modularizes the Wi-Fi package, the battery package, the SIM card package, and the camera package. In these embodiments, the system fits the modularized set of packages into a tray of the tablet computing device. The system also fits one or more CPU packages into the tray, which when combined with the modularized package, makes the tablet operationally functional.

In some embodiments, the electronic device is a desktop computing device. In these embodiments, the package and tray system modularizes the Wi-Fi package, the battery package, the SIM card package, and the camera package into a first package to fit into a first tray. The package and tray system of these embodiments also modularizes a plurality of CPU packages into a plurality of packages that fit into a set of other trays. In some embodiments, the first tray and the set of other trays are added to a dock to create a desktop media computing device. In some embodiments, the plurality of CPU packages comprises at least one cell phone processor.

### BRIEF DESCRIPTION OF THE DRAWINGS

Having described the invention in general terms, reference is now made to the accompanying drawings, which are not necessarily drawn to scale, and wherein:

FIG. 1 conceptually illustrates a hierarchy of interchangeable computing device components of a package and tray system in some embodiments.

FIG. 2 conceptually illustrates an example tray layout used in a package and tray system of some embodiments.

FIG. 3 conceptually illustrates another example tray layout used in a package and tray system of some embodiments.

FIG. 4 conceptually illustrates another example tray layout used in a package and tray system of some embodiments.

FIG. 5 conceptually illustrates another example tray layout used in a package and tray system of some embodiments.

FIG. 6 conceptually illustrates several packages of varying depths used in package and tray systems in some embodiments.

FIG. 7 conceptually illustrates a package and tray system used in a mobile computing device in some embodiments.

FIG. 8 conceptually illustrates a side perspective exploded view of an example package and tray system in some embodiments.

### DETAILED DESCRIPTION

In the following detailed description of the invention, numerous details, examples, and embodiments of the invention are described. However, it will be clear and apparent to one skilled in the art that the invention is not limited to the embodiments set forth and that the invention can be adapted for any of several applications.

Some embodiments of the invention provide a novel package and tray system that modularizes a set of interchangeable hardware device component packages that are placed on a set of trays configured to fit in an electronic device in order to provide functional operation of the hardware components by the electronic device. In some embodiments, the system includes at least one package and a tray. Each package fits into the tray by an alignment notch that aligns the package for interlocking within the tray. In some embodiments, the system includes a plurality of packages that simultaneously fit into the tray. In some embodiments, the plurality of packages comprises a CPU package, a memory package, a battery package, a Wi-Fi package, a SIM card package, and a camera package. In some embodiments, a minimum package configuration comprises the CPU package, the memory package, and the battery package.

Different embodiments of the system allow for packaging of different technology in small form factor, thereby permitting a consumer to upgrade device components (e.g., a set of cell phone components) in one or more easy to add packages. For example, a person has multiple options for interchanging one or more of the components of a mobile device by adding them to the tray, and then adding the tray into a smart phone, TV, or another device. Instead of upgrading an entire cell phone, each individual component or package of components (including everything from a touch screen, Wi-Fi components, cell packet technology, CPUs, GPUs, batteries, etc.), is completely modular and upgradable as needed. Such interchangeability prevents waste because it permits a user to pass on old packages to others (e.g., kids, friends, etc.), while allowing the user to retain any packages or components in the currently active device (e.g., a parent can keep the best screen).

In some embodiments, the electronic device is a mobile device. The mobile device of some embodiments is a smart phone. In these embodiments, the package and tray system modularizes a Wi-Fi package, a battery package, a SIM card package, and a camera package. The system in these embodiments fits the modularized set of packages into a tray of the smart phone to make the smart phone operationally functional.

To fit the packages into the smart phone, the minimum package configuration is installed according to one or more alignment notches that line the tray. Adding at least one of a SIM package, a Wi-Fi package, and a camera package adds operational performance to the smart phone.

In other embodiments, the mobile device is a tablet computing device. In these embodiments, the package and tray system modularizes the Wi-Fi package, the battery package, the SIM card package, and the camera package. In these embodiments, the system fits the modularized set of packages into a tray of the tablet computing device. The system also fits one or more CPU packages into the tray to make the tablet operationally functional.

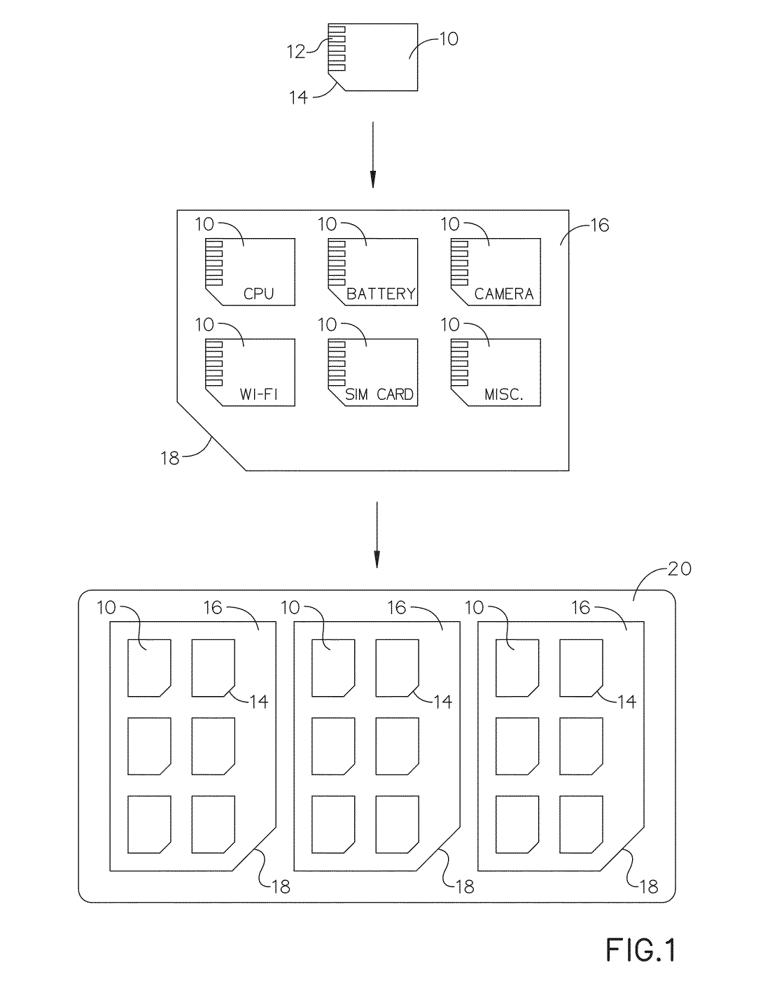

FIG. 1 conceptually illustrates a hierarchy of interchangeable computing device components of a package and tray system in some embodiments. A package is shown at the top of this figure. The package 10 includes a set of double-sided connectors 12 for connecting with a corresponding set of connectors of the computing device. The package 10 is shaped with a notch 14 that guides a user in aligning the package in a tray. In some embodiments, the package 10 includes a set of related hardware which provide a set of related operational features for the computing device.

In the middle of the hierarchy shown in FIG. 1 is a tray 16 that is configured to secure a plurality of packages 10 for use with a computing device. In this example, the plurality of packages placed in the tray 16 include a CPU package, a battery package, a camera package, a Wi-Fi package, a SIM card package, and another miscellaneous package (e.g., a Bluetooth package, stylus package, a display screen package, etc.). The tray 16 is shaped with an alignment guide 18 which allows the tray to be easily inserted into a compatible computing device.

At the bottom of the hierarchy shown in FIG. 1 is a tablet computing device 20 that is compatible with the tray 16. In some embodiments, a tablet computing device is configured to interface with a plurality of packages 10 placed in each of a plurality of trays 16. In particular, the tablet 20 in this example is configured to interface with up to six packages 10 in each of three trays 16. Thus, the tablet computing device 20 supports a variety of hardware components that are included in a variety of packages 10 to provide the tablet 20 a set of interchangeable functionality.

In some embodiments, the electronic device is a desktop computing device. In these embodiments, the package and tray system modularizes the Wi-Fi package, the battery package, the SIM card package, and the camera package into a first package to fit into a first tray. The package and tray system of these embodiments also modularizes a plurality of CPU packages into a plurality of packages that fit into a set of other trays. In some embodiments, the first tray and the set of other trays are added to a dock to create a desktop media computing device. In some embodiments, the plurality of CPU packages comprises at least one cell phone processor.

To fit the packages into the desktop computing device, the minimum package configuration components are installed according to one or more alignment notches that line the tray. Adding at least one of a SIM card package, a Wi-Fi package, and a camera package adds operational performance to the desktop computing device. In some embodiments, a plurality of different tray configurations is added to a dock of the desktop computing device. For instance, a first tray with a first CPU package and a second tray with a second CPU package may be added to a dock of the device to perform processor-intensive operations, such as math calculations, editing video, etc.

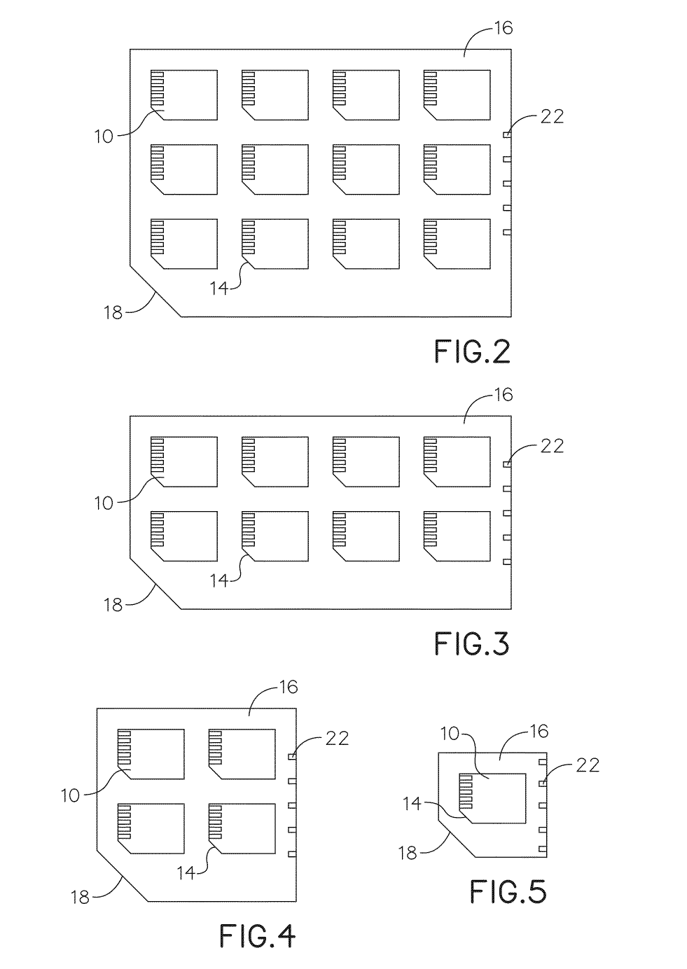

By way of example, FIGS. 2-5 conceptually illustrate different example tray layouts configured to secure different configurations of packages used in a package and tray system of some embodiments. In particular, FIG. 2 shows a first example tray 16 that is configured to secure up to twelve packages 10. Each package 10 is secured to the tray 16 when the notch 14 of the package is aligned with a corresponding notch in the tray 16. This alignment by the package notch 14 ensures that the set of double-sided connectors 12 of the package 10 are placed to interface with corresponding connectors of the computing device. Furthermore, the alignment guide 18 of the tray 16 ensures that that tray is installed only in a compatible computing device configured to align the guide 18 and secure the tray 16. The first example tray 16 also includes a set of docking connectors 22. In some embodiments, the docking connectors interlock with corresponding connectors of the computing device to lock the tray 16 in the appropriate position within the computing device.

In some embodiments, the package and tray system includes a security and activation system for interlocking each package and tray to the device. The security and activation system of some embodiments includes a challenge and response system for securing the initialization of each added package or tray. In some embodiments, the security and activation system includes a graphical user interface (GUI) displaying a set of challenge and response prompts to a user attempting to initialize one or more packages and/or trays. In some embodiments, the challenge and response prompts require the user to input a PIN and password combination. In addition, an email can be sent to notify the user of the changes to make sure the owner authorized the change. When a package is removed from a tray or when a tray is removed from a device, the challenge and response system is also activated.

Other specialized packages are also available for use in some embodiments, including in specialized industrial systems that use a temperature package and one or more sampling packages for a variety of industrial applications. In addition, other tray configurations are possible so that the package and tray system can be implemented in any type of electronic device, no matter its size. By way of example, FIG. 3 shows a second example tray 16 that is configured to secure up to eight packages 10, FIG. 4 shows a third example tray 16 that is configured to secure four packages 10, and FIG. 5 shows a fourth example tray 16 that is configured to secure one package 10. As these example trays demonstrate, a countless number of tray configurations available to compatibly use with any type of electronic device.

While the tray configurations vary according to the size of a compatible computing device and the number of packages that can be used with the compatible computing device, in some embodiments the package size varies. Package size varies along one physical dimension of the package (i.e., depth or height when the package is laying flat in a tray).

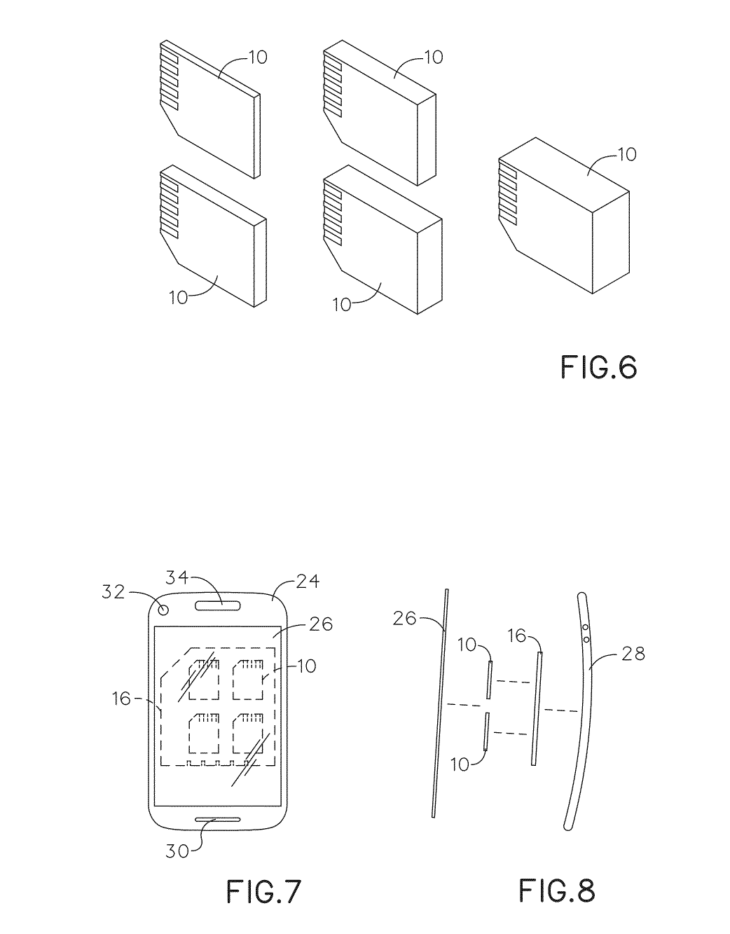

By way of example, FIG. 6 conceptually illustrates several packages of varying depths used in package and tray systems in some embodiments. By varying the depth or height of packages, more and/or different hardware device components can be included within a package, and thereby provide greater functionality to the computing device in which the package and tray system is used. Moreover, a tray can secure a package of any depth or height because the package only aligns with the tray according to a single orientation. Thus, only by placing the package, regardless of its height or depth, according to the single orientation will the tray be able to align the notch of the package to a corresponding notch of the tray and interconnect the double-sided connectors of the package to corresponding connectors of the computing device.

Given the flexibility of configuring different combinations of packages in a tray, the plurality of different tray configurations may be added to the dock of another electronic device, such as a laptop computing device, a smart TV, a computing system embedded in a vehicle, etc. Such different tray configurations are customized for the operational aspects of the corresponding device.

However, as each device has a particular set of hardware and/or a particular kernel, in addition to a specific size, the flexible configuration offered by many trays are limited. For example, many mobile computing devices have limited space within which to fit trays and limited widths within which packages can fit. FIG. 7 conceptually illustrates a package and tray system used in a mobile communications device that includes physical constraints that limit the number and size of trays and the configuration of packages that can be used in the device. As shown in this figure, the mobile communications device includes a receptacle 24, a removable receptacle screen 26, a microphone 30, a camera 32, and a speaker 34. Within the mobile communications device is a tray 16 (shown in dashed lines) securing four packages 10 (also shown in dashed lines). The four packages may include the four modularized packages that make up a minimum package configuration for a mobile device, including a Wi-Fi package, a battery package, a SIM card package, and a camera package. Furthermore, the size and configuration constraints may limit the tray options to only a single compatible tray for the mobile communication device.

The side of the mobile communication device also includes physical space limitations that constrain the height or depth of the packages 10 secured to the tray 16. By way of example, FIG. 8 conceptually illustrates a side perspective exploded view of an example package and tray system used in a mobile device. As shown, the mobile device includes a front display screen 26 and a back panel 28. Installed between the front display screen 26 and back panel 28 is the tray 16 and the packages 10. Given the relatively thin physical design of the mobile device, the package 10 are constrained in physical depth or height and the tray is constrained in both its depth dimension, as well as its two-dimensional surface space. Thus, while the package and tray system provides flexibility in packages and/or trays, some physical and system limitations of particular computing devices may constrain the options for using different tray and/or package configurations.

Nevertheless, by modularizing different combinations of component hardware devices in packages and trays, users can choose various technological functionality in a smart phone, a tablet, a computer, or any other electronic device configured to operate with a package and tray system. Thus, by creating a collection of packages that have the capability to represent the functions of a smart phone, a tablet, a computer, a smart TV, or a vehicle computer system, enormous resource savings is achieved (i.e., functional electronic components are not wasted).

The above-described embodiments of the invention are presented for purposes of illustration and not of limitation. While the invention has been described with reference to numerous specific details, one of ordinary skill in the art will recognize that the invention can be embodied in other specific forms without departing from the spirit of the invention. For instance, the packages may include a different type of notch to assist in aligning and securing the package to a tray, and the alignment guide of a tray may be designed different to provide compatibility with one or more electronic systems. Thus, one of ordinary skill in the art would understand that the invention is not to be limited by the foregoing illustrative details, but rather is to be defined by the appended claims.

I claim:

1. A package and tray system that allows a set of modularized hardware components of a first computing device to be used in a different second computing device, the package and tray system comprising:
a set of component hardware packages of the first computing device, each component hardware package being compatible with and providing a set of functionality to the first computing device and the second computing device; and
a tray comprising a set of alignment notches for aligning the set of component hardware packages within the tray, wherein when the tray is installed in the second computing device, the set of component hardware packages interfaces with a corresponding set of hardware components of the second computing device to provide the set of functionality to the second computing device.

2. The package and tray system of claim 1, wherein the set of packages comprises a minimum configuration of packages required to use the second computing device.

3. The package and tray system of claim 2, wherein the minimum configuration of packages comprises a CPU package, a memory package, and a battery package.

4. The package and tray system of claim 3, wherein (i) the CPU package comprises a CPU component that is compatible for use with each of the first computing device and the second computing device, (ii) the memory package comprises a memory component that is compatible for use with each of the first computing device and the second computing device, and (iii) the battery package comprises a battery that is compatible for use with each of the first computing device and the second computing device.

5. A package and tray system comprising:
a plurality of modularized component hardware device packages that provide functionality to a computing device;
a set of trays comprising (i) a first tray that is compatible with the particular computing device and is configured to connect a first set of packages from the plurality of modularized component hardware device packages to a first set of corresponding hardware components of the particular computing device and (ii) a second tray that is compatible with the particular computing device and is configured to connect a second set of packages from the plurality of modularized component hardware device packages to a second set of corresponding hardware components of the particular computing device;
a security system that validates compatibility of modularized component hardware device packages with the particular computing device, wherein when a package from the plurality of modularized component hardware device packages is added to the particular computing device, the security system validates compatibility of the the package using a set of challenge prompts that are displayed on a display screen device of the particular computing device; and
an activation system for initializing the added package on the particular computing device.

6. The package and tray system of claim 5 further comprising an interlocking system that locks at least one of the first tray and the second tray within the particular computing device.

7. The package and tray system of claim 6, wherein when the interlocking system locks a tray within the particular computing device, the security system validates compatibility of any packages installed in the tray and the activation system initializes any validated packages on the particular computing device.

8. The package and tray system of claim 5, wherein the first tray is a first size that fits a first quantity of packages and the second tray is a different second size that fits a different second quantity of packages.

9. The package and tray system of claim 8, wherein the first size is smaller than the second size and the first quantity of packages is less than the second quantity of packages.

10. The package and tray system of claim 9, wherein the first tray comprises a package that provides a particular set of functionality and the second tray comprises a same package that provides the particular set of functionality, wherein when the first tray is removed from the particular computing device and the second tray is installed in the particular computing device in place of the first tray, the same package is validated and active without the security system validating the same package and without the activation system initializing the same package.

11. The package and tray system of claim 9, wherein the second tray comprises a new package from the second set of packages that is not in the first set of packages, wherein when the first tray is removed from the particular computing device and the second tray is installed in the particular computing device in place of the first tray, the new package is validated for compatibility with the particular computing device by the security system and is initialized for use by the particular computing device by the activation system.
